(19) United States
(12) Patent Application Publication
(10) Pub. No.: US 2015/0372508 A1
(43) Pub. Date: Dec. 24, 2015

(54) METHOD OF CHARGING BATTERY

(71) Applicant: Hyundai Motor Company, Seoul (KR)

(72) Inventors: Sung Hoon CHOI, Suwon-Si (KR); Man Jae PARK, Gimpo-Si (KR)

(21) Appl. No.: 14/511,114

(22) Filed: Oct. 9, 2014

(30) Foreign Application Priority Data
Jun. 18, 2014 (KR) 10-2014-0074446

(51) Int. Cl. H02J 7/00; G01K 13/00; G01R 31/36

(52) U.S. Cl. CPC H02J 7/007; G01R 31/3606; G01K 13/00

(57) ABSTRACT

A method of charging a battery includes measuring a temperature of the battery. A target voltage responding to the temperature measured in the temperature measurement step is calculated. The battery is charged at a static current so as to reach the target voltage at a low temperature. Whether or not the difference between an average voltage of a plurality of battery cells consisting of the battery and the calculated target voltage occurs is determined when the static current-charging step is finished.

### CROSS REFERENCE TO RELATED APPLICATION

The present application claims the benefit of priority to Korean Patent Application Number 10-2014-0074446 filed on Jun. 18, 2014, the entire contents of which application are incorporated herein for all purposes by this reference.

### TECHNICAL FIELD

The present disclosure relates to a method of charging a battery, and more particularly, to a method of charging a battery capable of efficiently charging the battery in accordance with a voltage deviation between battery cells.

### BACKGROUND

Recently, portable electronic devices, such as a mobile phone, digital camera, notebook, and the like, have been widely used, and thus, a battery for supplying power to operate the electronic devices has been actively developed. Furthermore, the battery is a major component for a hybrid vehicle or an electric vehicle, and thus, more study recently has been concentrated on the battery for the hybrid vehicle or the electric vehicle.

As an example, according a method of rapid-charging, generally a battery is charged at a static current up to a chargeable voltage of a battery cell, and when it reaches the chargeable voltage, a static-voltage charging mode is performed thereby to rapidly charge the battery. Here, the chargeable voltage of the battery cell refers to a determined value considering lithium precipitation at a cathode when it is charged at a low temperature.

However, according to the conventional method of rapid-charging a battery, a static-voltage charging time is lengthened since a battery resistance is increased due to exposure to the low temperature and deterioration, and thus, a total charging time is increased, and further, the battery is not fully charged, thereby shortening driving distances on a single charge.

The description provided above as a related art of the present invention is just for helping in understanding the background of the present invention and should not be construed as being included in the related art known by those skilled in the art.

### SUMMARY

The present disclosure has been made in an effort to solve these problems and to provide a method for minimizing a battery charging time by calculating a target voltage of a battery responding to a temperature of the battery, considering a voltage deviation between batteries, and controlling a static current-charging time.

In one aspect of the present invention, a method of charging a battery includes measuring a temperature of the battery. A target voltage is calculated responding to the temperature measured in the temperature measurement step. The battery is charged at a static current to reach the target voltage at a low temperature. Whether or not the difference between an average voltage of a plurality of battery cells consisting of the battery and the calculated target voltage occurs is determined when the static current-charging step is finished.

The method of charging a battery may further include charging the battery at the static current until a battery cell maximum voltage reaches the calculated target voltage when the difference between the average voltage and the target voltage occurs.

The battery cell maximum voltage may be a maximum voltage of a cell among the plurality of cells.

The method of charging a battery may further include charging the battery at a static voltage when there is no difference between the average voltage and the calculated target voltage.

The static voltage-charging may be completed when the battery reaches a preset state of charge (SOC) or the current maintains for a predetermined time.

### BRIEF DESCRIPTION OF THE DRAWINGS

The above and other features of the present invention will now be described in detail with reference to certain exemplary embodiments thereof illustrated by the accompanying drawings which are given herein below by way of illustration only, and thus are not limitative of the present invention.

FIG. 1 is a flowchart illustrating a method of charging a battery according to an embodiment of the present invention.

FIG. 2 is a graph illustrating target voltages of a battery per temperature according to an embodiment of the present invention.

FIG. 3 is a graph illustrating the charging in a case where there is no voltage deviation between battery cells according to an embodiment of the present invention.

FIG. 4 is a graph illustrating the charging in a case where there is a voltage deviation between battery cells according to an embodiment of the present invention.

It should be understood that the appended drawings are not necessarily to scale, presenting a somewhat simplified representation of various features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION OF THE INVENTION

Hereinafter reference will now be made in detail to various embodiments of a method of charging a battery of the present invention, examples of which are illustrated in the accompanying drawings and described below. While the invention will be described in conjunction with exemplary embodiments, it will be understood that the present description is not intended to limit the invention to those exemplary embodiments. On the contrary, the invention is intended to cover not only the exemplary embodiments, but also various alternatives, modifications, equivalents, and other embodiments, which may be included within the spirit and scope of the invention as defined by the appended claims.

It is understood that the term “vehicle” or “vehicular” or other similar term as used herein is inclusive of motor vehicles in general such as, passenger automobiles including: sports utility vehicles (SUV); buses; trucks; various commercial vehicles, watercraft including: a variety of boats; and ships, aircraft, and the like, and includes hybrid vehicles, electric vehicles, plug-in hybrid electric vehicles, hydrogen-powered vehicles, and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

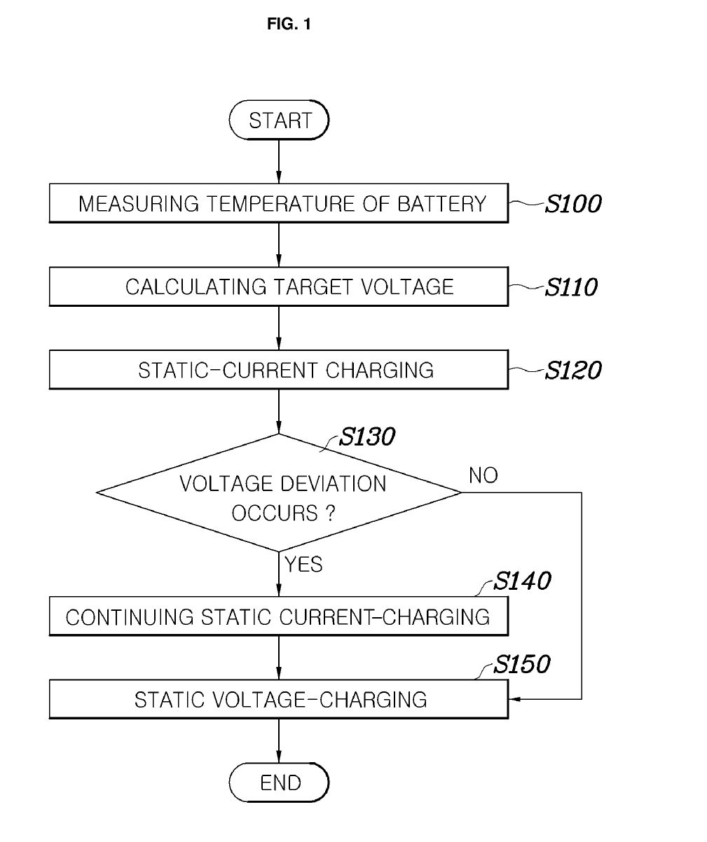

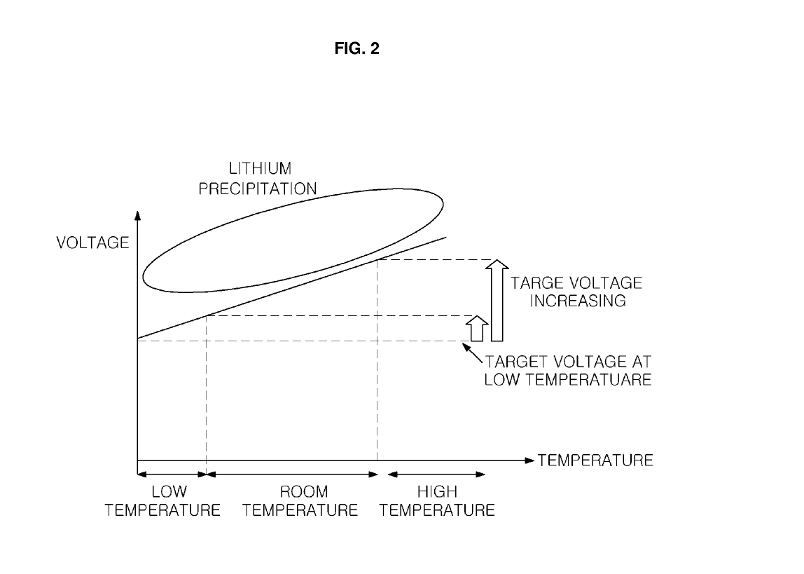

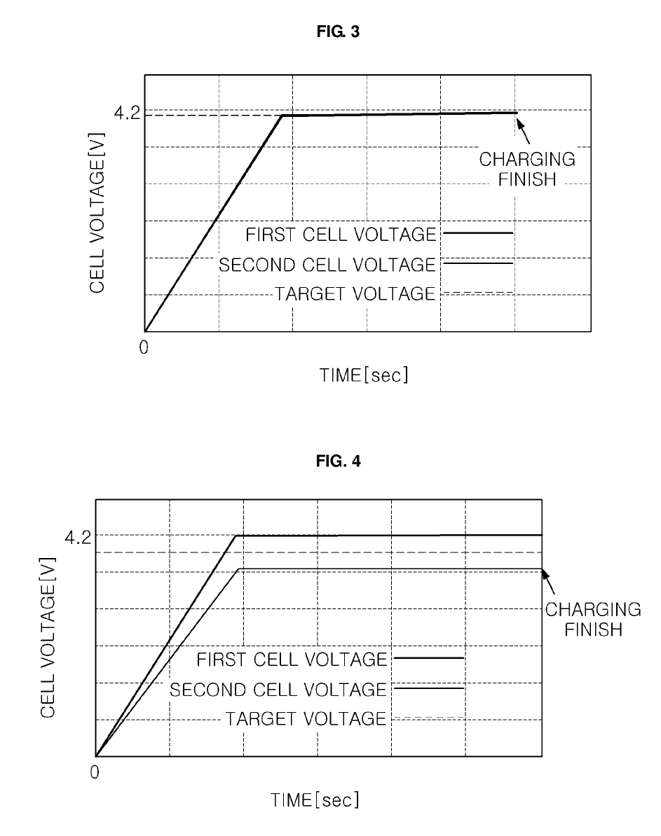

Hereinafter, an embodiment of the present invention will be described with reference to the accompanying drawings. FIG. 1 is a flowchart illustrating a method of charging a battery according to an embodiment of the present invention. FIG. 2 is a graph illustrating target voltages of a battery per temperature according to an embodiment of the present invention. FIG. 3 is a graph illustrating the charging in a case where there is no voltage deviation between battery cells according to an embodiment of the present invention. FIG. 4 is a graph illustrating the charging in a case where there is a voltage deviation between battery cells according to an embodiment of the present invention.

Referring to FIGS. 1 to 4, a method of charging a battery according to an embodiment of the present invention may include measuring a temperature of the battery (S100). A target voltage responding to the measured temperature is calculated (S110). The battery is charged at a static current so as to reach the target voltage at a low temperature (S120). Whether the difference between an average voltage of a plurality of battery cells consisting of the battery and the calculated target voltage occurs is determined when the step of charging the battery at the static current is finished (S130).

When the step of measuring the temperature of the battery is performed, the temperature of the battery may be measured by using battery management system (BMS) to be connected to the battery or by using a sensor separately provided.

Referring to FIG. 2, lithium may be precipitated in a case where a predetermined voltage or more is applied to a battery at a specific temperature. That is, in a case where the battery is charged at where the lithium is precipitated as shown in FIG. 2, lithium may be precipitated to decrease the performance of the battery, and thus, a charging time of the battery is delayed and the charging energy is decreased. Accordingly, the voltage at the moment when the lithium starts to be precipitated in the battery is set as a target voltage per temperature. At this time, it is shown in FIG. 2 that the target voltage increases as the temperature of the battery increases, and the target voltage decreases as the temperature of the battery decreases.

According to a related art, charging is performed such that a target voltage at a low temperature is set as a maximum voltage so as to simply prevent the precipitation of lithium. However, the present disclosure shortens the battery charging time compared to a conventional art, such that the target voltage is increased. When the voltage deviation is produced between cells consisting of the battery, which is described later, or a temperature of the battery is high, the static current-charging is performed up to the target voltage.

According to the present disclosure, the static current-charging is performed until it reaches the target voltage at the low temperature without performing the static current-charging so as to reach the target voltage, and then a difference between the average voltage of battery cells and the target voltage, namely, a voltage deviation is determined to determine whether the static current-charging continues. More detailed description thereof will be descried later.

With respect to the voltage deviation between the battery cells, as shown in FIG. 3, assuming that the target voltage at a low temperature is 4.2 V, a controller performs the static current-charging of the battery up to the target voltage at a low temperature at step S120. At this time, if a plurality of battery cells consisting of the battery have not been deteriorated, there is no voltage deviation between the battery cells up to the target voltage. That is, all the battery cells reach the target voltage at the low temperature. Accordingly, it is known that the present embodiment shows the battery in a normal state. The first cell voltage and second cell voltage as shown in FIGS. 3 and 4 refer to voltages of random battery cells consisting of the battery.

However, if the battery performance decreases due to the deterioration of the battery, the voltage of some battery cells such as the second cell voltage does not reach the target voltage at the low temperature, and thus, the average voltage of the battery cells becomes smaller than the target voltage at the low temperature. Accordingly, when the voltage deviation between the battery cells is produced, a large amount of current is not charged when performing the static current-charging and further the charging time is delayed.

If the difference between the average voltage and the target voltage occurs, the battery may be charged at the static current until the battery cell maximum voltage reaches the calculated target voltage (S140).

That is, if there occurs a difference between the average voltage of the plurality of battery cells consisting of the battery and the target voltage at the moment when the charging is completed after performing the static current-charging at step S120, the controller determines that the temperature of the battery is high or the battery cells are deteriorated, and thus further continues the static current-charging (S140). Thus, as a static current-charging time is lengthened, the battery charging time may be minimized and the charging energy may be increased.

At this time, the battery cell maximum voltage may be the voltage of a cell having a maximum voltage among the plurality of battery cells.

For example, in a case where the battery is not deteriorated even though the temperature of the battery is high, all the battery cells may be the battery cell maximum voltage. Accordingly, the static current-charging is further continued until the voltage of battery cells reaches a target voltage, thereby minimizing the battery charging time (S140).

On the contrary, if the battery is deteriorated, the voltage deviation between the battery cells is produced and as a result the voltage of the cell having a maximum voltage among the battery cells is set as the battery cell maximum voltage so as to prevent the lithium precipitation. Accordingly, in this case, the static current-charging is performed until the voltage of the battery having the maximum voltage reaches the target voltage, and thus, the charging time of the battery can be minimized while the lithium is not precipitated at step S140.

Further, in a case where the battery cell maximum voltage is the same as the target voltage even though the difference between the average voltage of the battery cells and the target voltage occurs, the battery is charged at the static current to prevent the deterioration of the battery since the lithium may be precipitated when the static current-charging is performed.

Additionally, in a case where there is no difference between the average voltage of the battery cells and the target voltage, the static voltage-charging of the battery may be performed (S150).

That is, if there is no difference between the average voltage of the battery cells and the target voltage, the temperature of the battery is low and the deterioration of the battery does not occur, and thus, the static voltage-charging is performed since the charging time can be minimized even if the static current-charging is not continued further at step S150.

Here, the step of charging the battery at a static voltage may complete the static current-charging in a case where the battery reaches a preset state of charge (SOC) or the current is maintained for a predetermined time.

The preset SOC may be set as 80% charging when the battery is charged on a rapid charging mode and as 95% charging when the battery is charged on a low charging mode. Further, the preset current indicates a cut off current wherein it may be set as a current where the charging does not proceed further.

According to the method of charging a battery as configured above, the static current-charging of the battery is performed up to a target voltage by controlling the target voltage per temperature, thereby shortening the charging time, and increasing a charging energy and a driving distance on a single charge.

Further, the static current-charging of a battery is performed up to the target voltage by sensing the voltage deviation between the battery cells, thereby preventing charging time from lengthening, increasing driving distance on a single charge, and performing a rapid charging of a battery.

The invention has been described in detail with reference to embodiments thereof. However, it will be appreciated by those skilled in the art that changes may be made in these embodiments without departing from the principles and spirit of the invention, the scope of which is defined in the appended claims and their equivalents.

What is claimed is:

1. A method of charging a battery comprising steps of:
measuring a temperature of the battery;
calculating a target voltage responding to the measured temperature;
charging the battery at a static current to reach the target voltage at a low temperature; and
determining whether a difference between an average voltage of a plurality of battery cells consisting of the battery and the calculated target voltage occurs when the step of charging the battery at the static current is finished.

2. The method of charging a battery of claim 1, further comprising a step of charging the battery at the static current until a battery cell maximum voltage reaches the calculated target voltage when the difference between the average voltage and the target voltage occurs.

3. The method of charging a battery of claim 2, wherein the battery cell maximum voltage is a maximum voltage of a cell among the plurality of cells.

4. The method of charging a battery of claim 1, further comprising a step of static voltage-charging the battery when there is no difference between the average voltage and the calculated target voltage.

5. The method of charging a battery of claim 4, wherein the static voltage-charging is completed when the battery reaches a preset state of charge (SOC) or the current maintains a preset current for a predetermined time.

6. The method of charging a battery of claim 1, wherein in the step of measuring the temperature of the battery, the temperature is measured by using battery management system (BMS) connected to the battery or by using a sensor separately provided.

7. The method of charging a battery of claim 1, wherein the target voltage increases as the temperature of the battery increases, and the target voltage decreases as the temperature of the battery decreases.
